(19) United States
(12) Patent Application Publication
(10) Pub. No.: US 2018/0168031 A1
(43) Pub. Date: Jun. 14, 2018

(54) ELECTRONIC DEVICE

(71) Applicant: DENSO CORPORATION, Kariya-city (JP)

(72) Inventor: Eiichi MATSUMOTO, Kariya-city (JP)

(73) Assignee: DENSO CORPORATION, Kariya-city (JP)

(21) Appl. No.: 15/712,274

(22) Filed: Sep. 22, 2017

(30) Foreign Application Priority Data
Dec. 9, 2016 (JP) 2016-239712

(51) Int. Cl. H05K 1/02; H05K 1/18; H05K 1/11

(52) U.S. Cl. CPC H05K 1/0271; H05K 1/181; H05K 2201/10977; H05K 2201/10636; H05K 1/111

(57) ABSTRACT

The present disclosure provides an electronic device including a printed board, an electronic component, a solder portion, and a sealing resin body. The electronic component is mounted on the printed board. The solder portion is electrically connecting the printed board and the electronic portion. The sealing resin body covers and seals the electronic component and the solder portion. The solder portion has tensile strength between 100 MPa and 110 MPa inclusive, and has breaking elongation between 21% and 24% inclusive. The sealing resin body has cure shrinkage ratio between 0.05% and 0.20% inclusive, thereby applying a compressive stress in an inward direction of the sealing resin body to the electronic component and the solder portion.

### CROSS REFERENCE TO RELATED APPLICATION

This application is based on reference Japanese Patent Application No. 2016-239712 filed on Dec. 9, 2016, the disclosure of which is incorporated herein by reference.

### TECHNICAL FIELD

The present disclosure relates to an electronic device formed by mounting an electronic component on a printed board by soldering process.

### BACKGROUND

Conventionally, when an electronic component is mounted on a printed board in an electronic device, electronic connection of therebetween is performed through soldering process. Such a solder may receive a variety of loads including cooling/heating loads, vibration, or impact depending on an environment under which the printed board and the electronic component are used. These loads may be a cause for generating cracks in the solder, which may lead to deteriorating performance reliability of the electronic device.

Patent Literature 1 (JP 2016-047555 A) discloses one solution where an intermetallic compound is formed in the solder by adjusting the composition of a lead-free solder alloy. As a result, expansion of the cracks into the solder can be prevented.

However, the solder described in Patent Literature 1 tends to have tensile strength greater than other conventional solders, and thus when the solder is used to connect the printed board and the electronic component, separation may occur due to the stress of deformation of the electronic component by aged-related deterioration.

In view of the above, it is an objective of the present disclosure to provide an electronic device where generation of cracks and separation from an electronic component can be suppressed.

### SUMMARY

An aspect of the present disclosure provides an electronic device including a printed board, an electronic component, a solder portion, and a sealing resin body. The electronic component is mounted on the printed board. The solder portion is electrically connecting the printed board and the electronic portion. The sealing resin body covers and seals the electronic component and the solder portion. The solder portion has tensile strength between 100 MPa and 110 MPa inclusive, and has breaking elongation between 21% and 24% inclusive. The sealing resin body has cure shrinkage ratio between 0.05% and 0.20% inclusive, thereby applying a compressive stress in an inward direction of the sealing resin body to the electronic component and the solder portion.

According to the above aspect of the present disclosure, the solder portion has tensile strength between 100 MPa and 110 MPa inclusive, and breaking elongation between 21% and 24% inclusive. Therefore, expansion of cracks in the solder portion can be suppressed. In addition, the sealing resin body having cure shrinkage ratio between 0.05% and 0.20% inclusive is used. Accordingly, compressive stress applies to the electronic component and the solder portion in an inward direction to press the solder portion and the electronic component against each other. As a result, generation of separation between the electronic component and the solder portion can be suppressed.

### BRIEF DESCRIPTION OF THE DRAWINGS

The above and other objects, features and advantages of the present invention will become more apparent from the following detailed description made with reference to the accompanying drawings. In the drawings:

FIG. 1 is a diagram schematically illustrating an electronic device according to a first embodiment;

FIG. 2 is a diagram illustrating a change of tensile stress over time acting between an electrode and a solder portion; and

FIG. 3 is a diagram schematically illustrating an electronic device according to a second embodiment.

### DETAILED DESCRIPTION

Next, a plurality of embodiments will be described below with reference to drawings. It is needless to say that following embodiments are some examples of the present disclosure, and therefore the present disclosure is not limited to these embodiment. Furthermore, each of the substantially same structures among the embodiments will be assigned to the respective common referential numeral and the description of the substantially same structures will be omitted in the subsequent embodiments.

### First Embodiment

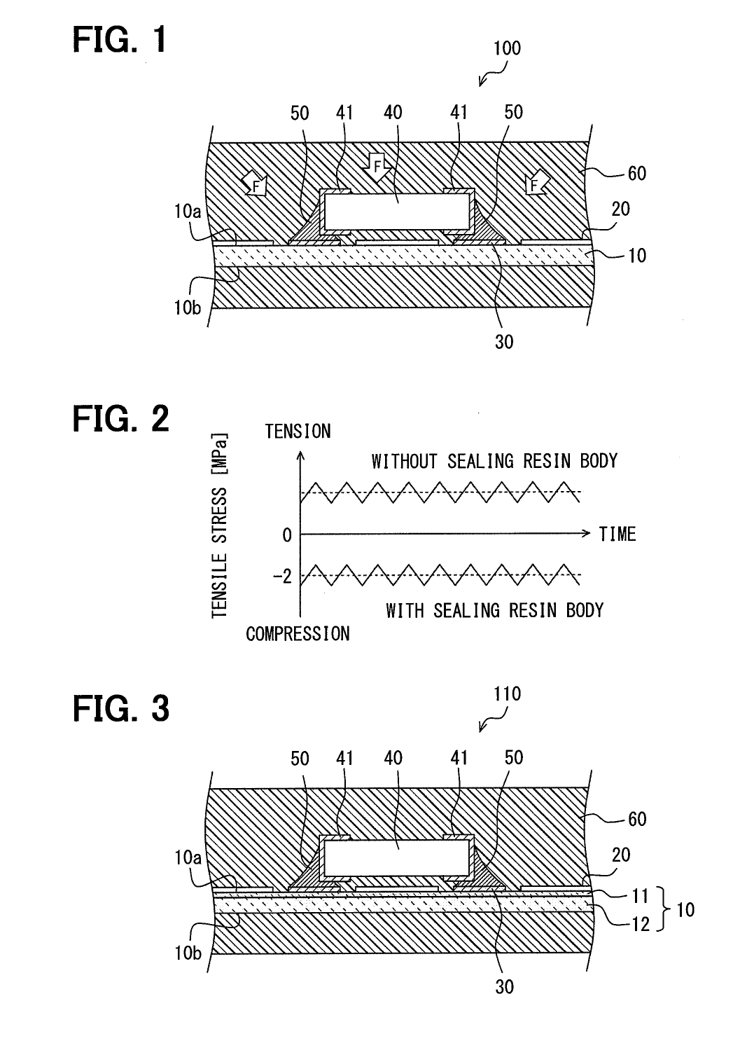

Referring to FIG. 1, the entire configuration of an electronic device according to the present embodiment will be schematically described.

The electronic device is an electronic control device to control a driving mechanism such as a motor. The electronic device is integrally formed with the driving mechanism to form a module and is assumed to be used under a harsh environment with a large temperature variation.

As shown in FIG. 1, the electronic device 100 includes a printed board 10 having a plate shape, a resist 20 protecting the printed board 10, a land 30 on which an electronic component is mounted, the electronic component 40, solder portions 50, and a sealing resin body 60.

The printed board 10 is an insulated substrate and has one surface 10a, on which the electronic component 40 is mounted, and the other surface 10b. The printed board 10 may be a single layer substrate or a multiple layers substrate. In this embodiment, a single layer substrate is used as the printed board 10.

The resist 20 is an insulation material applied onto the one surface 10a of the printed board 10. The resist 20 prevents a solder from adhering to unintended areas of the one surface 10a when the electronic component 40 is mounted on the one surface 10a. The resist 20 is formed on areas of the one surface 10a other than areas used for electric connection such as the land 30 on which the electronic component 40 is disposed. In other words, the electronic component 40 is connected to the one surface 10a at a position where the resist 20 is not applied to allow an electric conductor to be exposed.

The land 30 is formed on the one surface 10a of the printed board 10, and the electronic component 40 is mounted on the land 30. The land 30 and the electronic component 40 are electrically connected to each other. The land 30 is electrically connected to a wire (not shown) and a through hole, whereby the land 30 electrically connects the electronic component 40 on the land 30 to other electronic components connected to the wire or the through hole.

The electronic component 40 may be, but not limited to, a resistor or a capacitor, for example. In FIG. 1, a chip resistor is illustrated as one example of the electronic component 40. The electronic component 40 has a rectangular cuboid shape, and two electrodes 41 are disposed on surfaces of the electronic component 40 that are opposite to each other along a longitudinal direction of the electronic component 40.

Each of the solder portions 50 is a portion formed of a lead-free solder. The solder portion 50 is positioned between the land 30 and the electrode 41 of the electronic component 40 to electrically connect the land 30 to the electronic component 40. The solder of the solder portion 50 in this embodiment includes an argent (Ag), a copper (Cu), a bismuth (Bi), an antimony (Sb), and a nickel (Ni), in addition to a tin (Sn), and a cobalt (Co) and an indium (In) are added to the solder. The composition ratio of the solder portion 50 is, for example, 1.0-4.5 mass % of Ag, 0.6-0.8 mass % of Cu, 4-5 mass % of Bi, 2-5 mass % of Sb, 0.04-0.12 mass % of Ni, and 0.00-0.01 mass % of at least one element selected from Co and In are added, and the remainder of the solder portion 50 is formed of Sn. The elemental composition of solder portion 50 is determined so that the solder portion 50 has tensile strength between 100 MPa and 110 MPa inclusive, and breaking elongation between 21% and 24% inclusive when the solder portion 50 is in a solid state connecting the land 30 and the electronic component 40.

The sealing resin body 60 is, e.g., an epoxy resin, and a filler is added. The filler may be formed of silica as an extender material and aluminium hydroxide as a fire-resistant material. 60-70 mass % of the filler is added to the sealing member 50. The filler is formed of particles having radiuses between 10-100 μm. The sealing resin body 50 houses the printed board 10 therein to cover at least the electronic component 40, the land 30 on which the electronic component 40 is mounted, and the solder portion 50 connecting the electronic component 40 and the land 30. The sealing resin body 60 is formed by casting, and during curing, a compressive stress F compressing the elements housed therein generates. Especially, in this embodiment, the type and amount of the filler are determined so that the sealing resin body 60 has cure shrinkage ratio between 0.05% and 0.20% inclusive, and has a linear expansion coefficient between 13 ppm and 17 ppm inclusive. It should be understood that the cure shrinkage ratio is a volume change ratio of the resin before and after curing.

Referring to FIG. 2, operation and advantages according to the electronic device 100 of the present embodiment will be described.

As described above, the composition of solder portion 50 is determined so that the solder portion 50 has tensile strength between 100 MPa and 110 MPa inclusive, and breaking elongation between 21% and 24% inclusive. Therefore, the durability of the solder portion 50 can be improved as compared to a situation where a conventional solder is used. It should be noted that a conventional solder may be formed of an argent (Ag) and a copper (Cu) in addition to a tin (Sn), and the composition thereof may be 3.0 mass % of Ag, 0.5 mass % of Cu, and the remainder of Sn. Further, such a conventional solder may typically have tensile strength between 53-55 MPa and breaking elongation between 55-57%.

In the solder portion 50 of the present embodiment, a force applies to the electro component 40 along a direction to separate the electrode 41 and the solder portion 50 away from each other, in other words, along a tensile direction under a condition without an external force. For example, if the electronic device 100 is exposed to a heating/cooling cycle environment without the sealing resin body 60, a positive tensile stress applies, on average, between the electrode 41 and the solder portion 50, as shown in FIG. 2. In other words, separation of the electrode 41 and the solder portion 50 likely occurs.

However, the electronic device 100 of the present embodiment includes the sealing rein body 60. As described above, the sealing resin body 60 has cure shrinkage ratio between 0.05% and 0.20% inclusive. As a result, a negative tensile stress during heating/cooling cycle generates and the value of the tensile stress has about 2 MPa on average. Thus, the tensile stress of the sealing resin body 60 applies in a direction to press the electronic component 40 and the solder portion 50 against each other, whereby separation between the electrode 41 and the solder portion 50 can be suppressed.

In this way, according to the electronic device 100 of the present embodiment, it is possible to suppress occurrence of cracks in the solder portion 50 and separation between the electrode 41 and the solder portion 50.

Furthermore, the sealing resin body 60 of the present embodiment has a linear expansion coefficient between 13 ppm and 17 ppm inclusive. Since a printed board generally has about 14 ppm of a linear expansion coefficient, the linear l expansion coefficient of the sealing resin body 60 is substantially the same as the printed board 10. As a result, separation due to the difference between the linear expansion coefficients of the sealing resin body 60 and the printed board 10 under cooling/heating cycle can be suppressed.

### Second Embodiment

The electronic device 110 according to the second embodiment has a different structure of the printed board 10 from the electronic device 100 of the first embodiment.

The printed board 10 of the electronic device 110 includes a mounting substrate 11 on the one surface 10a serving a mounting surface for the electronic component 40 and a supporting substrate 12 on the other surface 10b to support the mounting substrate 11. The mounting substrate 11 is formed of a flexible resin having low elastic modulus and a large stretch ratio and an epoxy resin having a high heat-resisting property. The mounting substrate 11 includes about 50-80 mass % of the flexible resin and the epoxy resin. The elastic modulus of the one surface 10a is about 8 GPa. On the other hand, the supporting substrate 12 is mainly formed of an epoxy resin, a copper foil, and a glass cloth. The elastic modulus of the supporting substrate 12 is about 16 GPa.

In this way, by setting the elastic modulus of the mounting substrate 11 including the mounting surface to be lower than the supporting substrate 12, the stress by the printed board 10 applied to the solder portion 50 can be relieved. As a result, deformation of the solder portion 50 can be suppressed, and therefore a strain by the solder portion 50 to the electrode 41 can be reduced. Thus, cracks much less likely generate in the solder portion 50.

### Other Embodiments

Although the description of the above embodiments is merely an example, and the present disclosure is not necessarily limited to the embodiments. Thus, a variety of modifications may be applied to the above embodiments unless exceeding the scope of the present disclosure.

As described in the above embodiments, if the sealing resin body 60, which applies a compressive stress to the electric component 40 and the solder portion 50, is not used, a flux residue on the one surface 10a of the printed board 10 may be a cause of separation of the solder portion 50 and the electrode 41 of the electronic component 40. Therefore, such a flux residue is preferably removed as much as possible from the printed board 10 through a cleaning process. However, the cleaning process takes up substantially percentage of entire manufacturing process, and therefore the cleaning process may also lead to increasing the cost. Hence, there is a cost advantage if the cleaning process is avoided. In this regard, since the sealing resin body 60 presses the electronic component 40 and the solder portion 50 in the inward direction in the above-described embodiments, a certain amount of flux residues can be acceptable. In other words, the cleaning process for the flux residue may be eliminated.

In the above-described embodiments, the chip resistor is used as one example of the electronic component 40. However, other types of electronic components may be used.

What is claimed is:

1. An electronic device comprising:
a printed board;
an electronic component mounted on the printed board;
a solder portion electrically connecting the printed board and the electronic portion; and
a sealing resin body covering and sealing the electronic component and the solder portion, wherein
the solder portion has tensile strength between 100MPa and 110MPa inclusive, and has breaking elongation between 21% and 24% inclusive, and
the sealing resin body has cure shrinkage ratio between 0.05% and 0.20% inclusive, thereby applying a compressive stress in an inward direction of the sealing resin body to the electronic component and the solder portion.

2. The electronic device according to claim 1, wherein
the sealing resin body has a linear expansion coefficient between 13 ppm and 17 ppm inclusive.

3. The electronic device according to claim 1, wherein
the printed board includes a mounting substrate on which the electronic component is mounted and a supporting substrate that supports the mounting substrate, the mounting substrate being laminated onto the supporting substrate, and
the mounting substrate has an elastic modulus that is less than that of the supporting substrate.

4. The electronic device according to claim 3, wherein
the elastic modulus of the mounting substrate is 8 GPa.

5. The electronic device according to claim 1, wherein
the sealing resin body is an epoxy resin.

6. The electronic device according to claim 1, wherein
the printed board includes a flux residue on one surface of the printed board on which the electronic component is mounted.
